(19) United States
(12) Patent Application Publication
(10) Pub. No.: US 2008/0265913 A1
(43) Pub. Date: Oct. 30, 2008

(54) Sealed Capacitive Rain Sensor

(75) Inventor: Yishay Netzer, Misgav (IL)

Correspondence Address: DR. MARK M. FRIEDMAN;C/O BILL POLKINGHORN - DISCOVERY DISPATCH, 9003 FLORIN WAY, UPPER MARLBORO, MD, 20772, US

(73) Assignee: Tamar Sensors Ltd., D.N. Misgav 20142 (IL)

(21) Appl. No.: 12/065,617

(22) PCT Filed: Sep. 6, 2006
(86) PCT No.: PCT/IL06/01035

§ 371 Date: Mar. 4, 2008

Related U.S. Application Data
(60) Provisional application No. 60/713,734, filed on Sep. 6, 2005.

(51) Int. Cl. G01R 27/26

(52) U.S. Cl. 324/669

(57) ABSTRACT

A capacitive rain sensor for activating automotive window wipers includes: capacitive plates, electronic circuitry for sensing the capacitance between said plates, processing the sensed capacitance signal, and generating wipe commands. The capacitive plates are protected from water adsorption and condensation by means of a hermetic enclosure. The interconnection between the inside and outside of the enclosure is optionally implemented by means of conductors printed on the window. Wiper-induced and other parasitic signals are rejected by means of an adaptive filter Optional radiation sensor is utilized to suppress solar induced fast temperature variations. An optional far-field cancellation plate is utilized to minimize false wipes due to nearby objects.

### BACKGROUND OF THE INVENTION

Automotive optical rain sensors for automating the wiper operation are becoming increasingly popular despite known drawbacks such as: false wipes and sensitivity to deposited salt. On the other hand, capacitive rain sensors have not matured to be accepted by the automotive industry, despite their claimed advantages.

Capacitive rain sensors as described in the patent literature are based on conductive electrodes—or plates, deposited on the glass and constituting a sensing capacitance that is influenced by raindrops on the external window surface through its near electrostatic field.

Automotive windows may consist of a single glass plate, or of laminated glass plates. Although the inner window surface is easily accessible it has been rarely considered as viable for deploying the sensing plates because the full glass thickness—typically around 5.5 mm, separating the sensed raindrop. As a result, the capacitance changes due to raindrops are minute and the resulting low-level signal is susceptible to parasitic effects. As an example, temperature variations of the windshield, combined with the temperature dependence of the glass dielectric constant, result in random changes in the measured capacitance, which may lead to false wipes. U.S. Pat. No. 6,373,263 addressed this issue by incorporating an auxiliary compensation capacitance adjacent to the sensing capacitance—see FIG. 1.

Despite such improvements prior art capacitive rain sensors were inadequate for handling small rain droplets such as due to mist build up on the windshield. Typically mist produces a signal of the order of 10 mV, compared to hundreds of mV due to rain. Coping with mist situations requires much higher sensitivity and suppression of interfering factors, which were unrecognized in prior art. Typically, prior art rain sensors process fast varying signals due to raindrops and reject the slow, temperature induced, parasitic signals. However, such filtering would also reject mist-induced signals due to their slow build up. Similarly, prior art ignored interfering signals generated by the variable parasitic capacitance between the wipers and the rain sensing plates.

Although prior art recognized the adverse effects of condensation on the sensing plates, the effect of water adsorption, or sorption, to be described later, was not appreciated, Adsorption-induced signals are negligible compared to raindrops but may be detrimental to detecting mist deposition.

### SUMMARY OF THE INVENTION

The present invention deals with capacitive rain sensors deployed on the inner window surface, with superior sensitivity, while minimizing false wipes.

A first aspect of the invention is the elimination of adsorption effects by hermetically sealing the capacitive sensing plates.

A second aspect of the invention is the use of a radiation sensor for rejecting signals due to sudden solar radiation variations.

A third aspect of the invention is signal processing for eliminating false wipes due to wiper interaction with the rain sensor.

A fourth aspect of the invention is cancellation of the far electrostatic field around the sensor for minimizing false wipes due to nearby objects on the inner side of the window.

A fifth aspect of the invention is simplifying the electrical interconnection between the sealed protective enclosure and the outside, by means of printed conductors on the glass.

A sixth aspect of the invention is the application of the capacitive plates using an adhesive sticker

A further aspect of the invention is the use of transparent capacitive plates (electrodes), thereby reducing direct radiant heating of the electrodes and the adjacent dielectric (glass).

Each of the aforementioned aspects of the invention is believed to be of patentable significance in its own right, and the aspects can advantageously be combined in synergy to provide various particularly preferred implementations of the present invention.

Thus, there is provided, according to the teachings of the present invention, a vehicular capacitive rain sensor deployed on an Internal surface of a window, the sensor having a sensing region for detecting moisture on the external surface of the window for generating wipe commands applied to a wiper deployed for wiping the external surface, the sensor comprising: (a) at least two electrodes disposed on the internal surface and constituting a capacitance, the at least two electrodes defining a sensing region on the external surface of the window within which the presence of water detectably affects the capacitance; (b) a housing arrangement cooperating with the internal surface of the window to enclose the electrodes, at least part of the housing arrangement being implemented as an electrostatic shield for shielding the electrodes; and (c) electrical interconnections passing into the housing arrangement; wherein the housing arrangement is configured to hermetically seal the electrodes so as to make the capacitance substantially insensitive to moisture adsorption.

According to a further feature of the present invention, there is also provided electronic circuitry associated with the electrodes and configured to generate an output signal indicative of the capacitance.

According to a further feature of the present invention, there is also provided a processing system for generating wipe commands derived from the output signal;

According to a further feature of the present invention, the processing system is configured to provide a filter with a dynamic behavior that varies depending on the output signal.

According to a further feature of the present invention, the processing system is configured such that: (a when the wiper is not activated the processing system filters the output signal to discard variation with a frequency of less than a first cut-on frequency; and (b) when the wiper is activated, the processing system filters the output signal to discard variation with a frequency of less than a second cut-on frequency, the second cut-on frequency being higher than the first cut-on frequency.

According to a further feature of the present invention, the electrical interconnections are implemented as printed conductors on the internal surface. According to a further feature of the present invention, the housing arrangement is implemented primarily from conductive material so as to provide the electrostatic shield.

According to a further feature of the present invention, there is also provided a detector for detecting solar radiation, the processing system being responsive to an output from the detector when the wiper is not activated to prevent generation of a wipe command within a given time period after an abrupt increase in solar radiation.

According to a further feature of the present invention, the at least two electrodes are deposited on a surface of a flexible non-conductive layer configured for attachment to the internal surface of the window.

According to a further feature of the present invention, the at least two electrodes and the flexible non-conductive layer are substantially transparent.

According to a further feature of the present invention, the flexible non-conductive layer is coated with an adhesive for attachment to the internal surface of the window.

According to a further feature of the present invention, the at least two electrodes are substantially transparent.

According to a further feature of the present invention, a first of the at least two electrodes is driven with a signal so as to generate a near electrostatic field at least in the sensing region and a far electrostatic field, the capacitive rain sensor further comprising a third electrode which is driven with an opposite signal and configured so as to generate a second far electrostatic field which opposes at least part of the far electrostatic field of the first electrode.

There is also provided according to the teachings of the present invention, a vehicular capacitive rain sensor deployed on an internal surface of a window, the sensor having a sensing region for detecting moisture on the external surface of the window for generating wipe commands applied to a wiper deployed for wiping the external surface, the sensor comprising: (a) at least two electrodes disposed on the internal surface and constituting a capacitance, the at least two electrodes defining a sensing region on the external surface of the window within which the presence of water detectably affects the capacitance; (b) a housing arrangement cooperating with the internal surface of the window to enclose the electrodes, at least part of the housing arrangement being implemented as an electrostatic shield for shielding the electrodes; (c) electronic circuitry associated with the electrodes and configured to generate an output signal indicative of the capacitance; and (d) a processing system for generating wipe commands derived from the output signal, wherein the processing system being configured such that: (i) when the wiper is not activated, the processing system filters the output signal to discard variation with a frequency of less than a first cut-on frequency; and (ii) when the wiper is activated, the processing system filters the output signal to discard variation with a frequency of less than a second cut-on frequency, the second cut-on frequency being higher than the first cut-on frequency.

There is also provided according to the teachings of the present invention, a vehicular capacitive rain sensor deployed on an internal surface of a window, the sensor having a sensing region for detecting moisture on the external surface of the window for generating wipe commands applied to a wiper deployed for wiping the external surface, the sensor comprising: (a) at least two electrodes disposed on the internal surface and constituting a capacitance, the at least two electrodes defining a sensing region on the external surface of the window within which the presence of water [symbol] internal surface of the window to enclose the electrodes, at least part of the housing arrangement being implemented as an electrostatic shield for shielding the electrodes; and (c) electronic circuitry associated with the electrodes and configured to generate an output signal indicative of the capacitance; (d) a processing system for generating wipe commands derived from the output signal, and (e) a detector for detecting solar radiation, the processing system being responsive to an output from the detector when the wiper is not activated to prevent generation of a wipe command within a given time period after an abrupt increase in solar radiation.

There is also provided according to the teachings of the present invention, a vehicular capacitive rain sensor deployed on an internal surface of a window, the sensor having a sensing region for detecting moisture on the external surface of the window for generating wipe commands applied to a wiper deployed for wiping the external surface, the sensor comprising: (a) at least two electrodes disposed on the internal surface and constituting a capacitance, the at least two electrodes defining a sensing region on the external surface of the window within which the presence of water detectably affects the capacitance; and (b) a housing arrangement cooperating with the internal surface of the window to enclose the electrodes, at least part of the housing arrangement being implemented as an electrostatic shield for shielding the electrodes, wherein the at least two electrodes are deposited on a surface of a flexible non-conductive layer configured for attachment to the internal surface of the window.

According to a further feature of the present invention, the at least two electrodes and the flexible non-conductive layer are substantially transparent.

According to a further feature of the present invention, the flexible non-conductive layer is coated with an adhesive for attachment to the internal surface of the window.

There is also provided according to the teachings of the present invention, a vehicular capacitive rain sensor deployed on an internal surface of a window, the sensor window for generating wipe commands applied to a wiper deployed for wiping the external surface, the sensor comprising: (a) at least two electrodes disposed on the internal surface and constituting a capacitance, the at least two electrodes defining a sensing region on the external surface of the window within which the presence of water detectably affects the capacitance; (b) a housing arrangement cooperating with the internal surface of the window to enclose the electrodes, at least part of the housing arrangement being implemented as an electrostatic shield for shielding the electrodes, wherein the at least two electrodes are substantially transparent.

There is also provided according to the teachings of the present invention, a vehicular capacitive rain sensor deployed on an internal surface of a window, the sensor having a sensing region for detecting moisture on the external surface of the window for generating wipe commands applied to a wiper deployed for wiping the external surface, the sensor comprising: (a) at least two electrodes disposed on the internal surface and constituting a sensing capacitance, the at least two electrodes defining a near electrostatic field sensing region on the external surface of the window within which the presence of water detectably affects the capacitance, the electrodes further forming a far electrostatic field; (b) at least one compensation electrode configured for forming a compensatory far electrostatic field for selectively opposing at least part of the far electrostatic field of the sensing capacitance; (c) a housing arrangement cooperating with the internal surface of the window to enclose the electrodes, at least part of the housing arrangement being implemented as an electrostatic shield for shielding the electrodes; and (d) electronic circuitry associated with the electrodes and configured to generate an output signal indicative of the sensing capacitance; and (e) a processing system for generating wipe commands derived from the output signal, wherein the electronic circuitry drives a first of the at least two electrodes with a sensing signal and the compensation electrode with an opposite signal such that at least part of the far electrostatic field of the first electrode is reduced. Although reference is made mainly to windshields, the present invention is applicable to rear windows, roof windows, and external mirrors as well.

### BRIEF DESCRIPTION OF THE DRAWINGS

FIG. 1 is a schematic plan view of a layout of capacitive plates of a prior art rain sensor, referred to above.

FIG. 2 is a graphic representation of a measured signal versus sensed raindrop diameter in a typical capacitive rain sensor.

FIG. 3-a and FIG. 3-b are schematic plan views illustrating two alternative layouts of capacitive plates in accordance with preferred embodiments of the invention.

FIG. 4 is a partially cut-away isometric view showing a hermetic enclosure according to a first embodiment of the invention

FIG. 5 is an isometric view of a hermetic enclosure with printed conductors according to a second embodiment of the invention.

FIG. 6 is a schematic plan view illustrating a layout of circular capacitive plates, including a photo sensor.

FIG. 7 is a signal flow diagram of a preferred signal processing arrangement.

FIG. 8 is a cross sectional view taken through a circular capacitive rain sensor that includes a far-field generating plate for minimizing parasitic sensitivity to nearby objects.

FIG. 9 is a cross-sectional view taken through a non-compensated circular rain sensor, constructed and operative in accordance with a preferred embodiment of the invention, showing constant-potential lines in the vicinity of the sensor.

FIG. 10 is a cross-sectional view taken through a compensated rain sensor, constructed and operative in accordance with a preferred embodiment of the invention, showing constant-potential lines in the vicinity of the sensor.

### DESCRIPTION OF THE PREFERRED EMBODIMENT

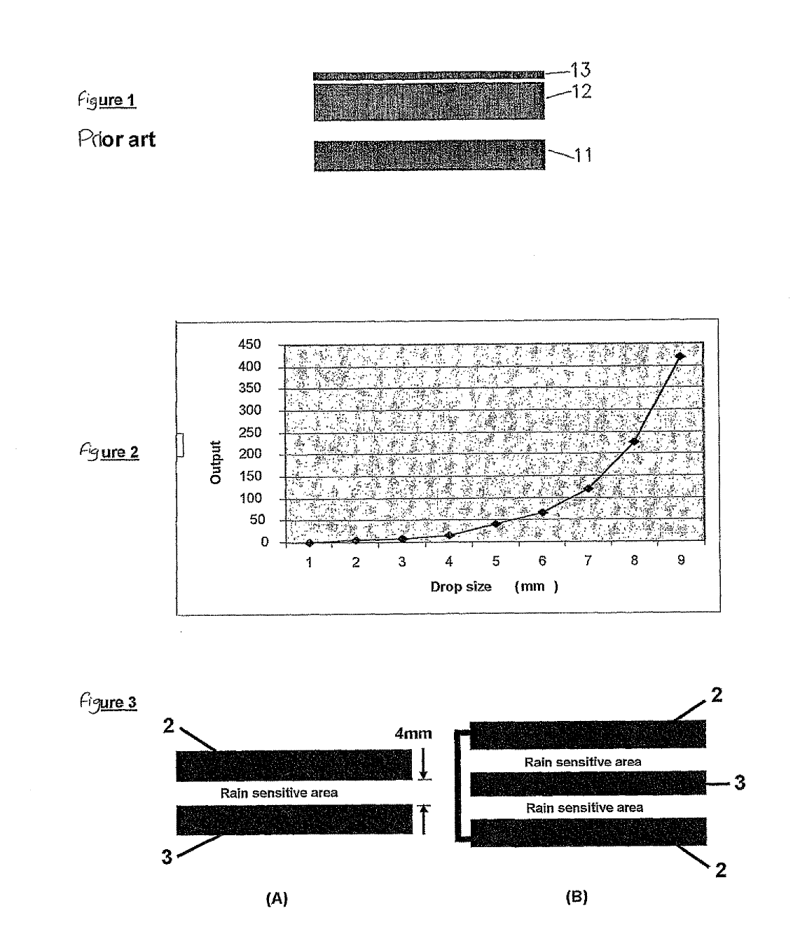

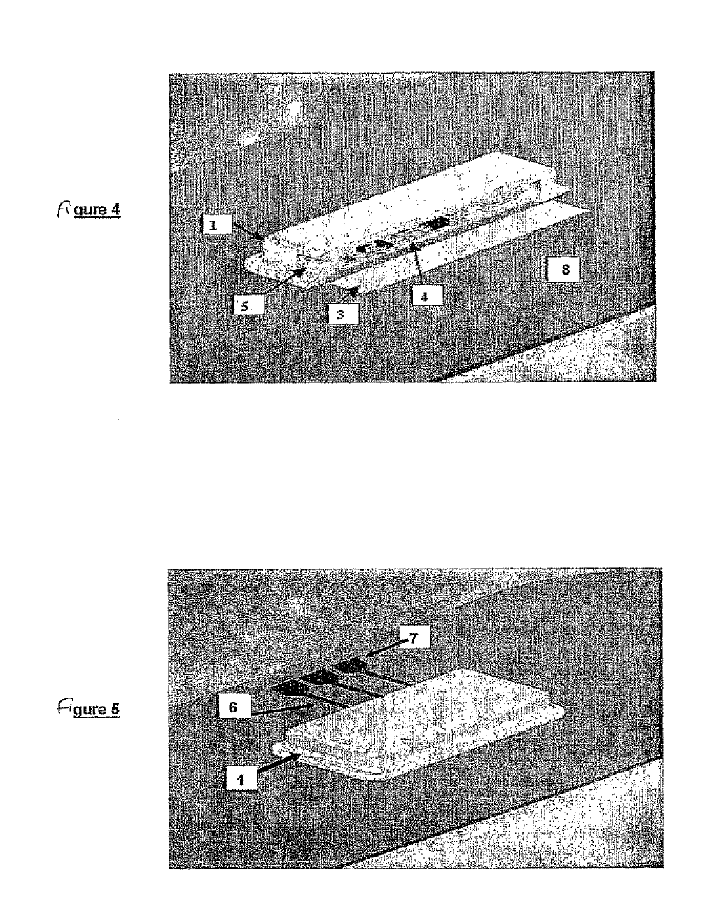

FIG. 2 illustrates the measured output voltage in a capacitive rain sensor using the plates shown in FIG. 3-a deposited on a glass of 5.5 mm thick, as a function of sensed droplet diameter. Even though the measured values relate to small droplets sprayed on the sensitive area. A practical consequence is that mist, such as from passing traffic on wet roads, results in a hard-to-discriminate signal which, unlike raindrops, also builds up slowly. As a result, attempts to detect mist with prior art capacitive rain sensors by merely lowering the decision threshold, or increasing gain, result in false wipes due to parasitic signals that were negligible when dealing with raindrop detection only. For example, in tests, false wipes (i.e., unnecessary actuation of the wipers) were encountered at dusk times, with no apparent reason. This phenomenon only disappeared after the sensing plates were dried and hermetically sealed. Their origin was traced to be the relatively obscure adsorption phenomenon described in the following citation from the instruction manual of the Hydrosorb 1000 Automated Water Sorption Analyzer, manufactured by Quantachrome instruments www.quantachrome.com under the title WATER VAPOR SORPTION THEORY:
“Water is adsorbed, at least to some extent, by the surface of most solids.

The amount of water adsorbed is a function of the affinity between the surface and water molecules, temperature, water vapor concentration (i.e. pressure, be it expressed as partial pressure, relative pressure, relative humidity or water activity) and, of course, the absolute amount of exposed surface area. In addition to those molecules that adsorb directly onto the surface of the solid, additional molecules may condense in pores depending on the pore size.
The affinity between water and the surface depends not only on weak dispersion forces, but also electrostatic forces and more specific forces associated with the formation of hydrogen bonds. The strength of the hydrogen bond depends on the chemical nature of the surface, especially the presence of oxygen. Hydroxyl groups also play an important role, particularly in silicas (silicon oxides), which bear differing amounts of hydroxyl groups at the surface depending on treatment temperature.”

Given that glass is basically Silicon Dioxide (SiO₂) it is especially prone to moisture sorption which, unlike conventional condensation, does not occur at any particular relative humidity, and is too thin to be visible. Also whereas merely covering the capacitive plates, as in prior art, can usually minimize condensation, hermetic sealing is mandatory for preventing adsorption. The term “hermetic” is used herein in the description and claims to refer to any seal which prevents inflow or outflow of air under normal operating conditions of the system. In most preferred cases, the housing is also made of materials and assembled in such a manner as to be substantially impervious to water vapor.

Prior art rain sensors have been found effective for detecting raindrops due to the resulting large signals (variations in capacitance), which are easily discriminated against slowly varying glass temperature. Although a high pass filter with 1 Hz cut on frequency is effective to pass raindrop signals and reject temperature induced output variations, it also rejects the slowly building mist signal. Typically a cut on frequency as low as 0.05 Hz, would be needed to pass the mist signals and still reject temperature induced signals.

To sum up: the sensor can issue outputs of the following types:
1. Fast rate of change, resulting from either raindrops, or parasitic solar induced thermal transients. The two signals are transmitted by the high pass filter and the parasitic signal is discarded with the help of a radiation detector (to be discussed later)
2. Medium rate of change, resulting from mist buildup and transmitted by the high pass filter with a suitably-chosen cut-on frequency, such as 0.05 Hz.
3. Slow rate of change, due to surrounding air temperature variations. The 0.05 Hz high pass filter would largely attenuate these signals and pass the mist signals.

It has been found, however, that use of a high-pass filter with the low frequency

Specifically, it was observed that wiper operation sometimes fails to stop even after the window was cleared dry. The reason was traced to a parasitic signal generated through capacitive coupling between the wiper blades passing over the sensing plates. As is well known to those skilled in the art, the time taken by the filter output to decay and recover from an input signal, is inversely proportional to its cut on frequency, i.e., roughly 20 seconds for a 0.05 Hz cut on filter. This means that the signals induced by the wiper as well as by recent rain drops, could persist long after the windshield is dry; and every wipe triggers another one.

This complication is advantageously resolved by using filtering with characteristics that depend on the circumstances, i.e., “adaptive filtering”. In one embodiment more than one filter are used. For example, one filter with a cut-on frequency of 0.05 Hz, with a decay time long relative to a wipe cycle and a second filter with a cut on frequency of 2 Hz and a decay time short compared to a wipe cycle. According to this approach, the first filter is used when the system is in a stand-by status, i.e., no rain, the second filter is switched in once a first wipe is initiated, and preferably replaces the function of the first filter. In a particularly preferred embodiment, after the first filter is switched out, its content is cleared of any past history so that once the wiper stops and the system reverts to standby, it is ready to be switched in again without traces of past signals. It is well known to those skilled in the art that more sophisticated adaptive filtering can be implemented using digital techniques. It should be noted that all processing which is effective to select signals having frequencies only above a certain value, or within a certain range, is referred to herein as “filtering”, even if the digital processing techniques used are not commonly referred to in that manner.

FIG. 3-a illustrates a layout of sensing electrodes (plates) of a first preferred embodiment of the invention. The sensing plates are preferably printed on the window front (outside) surface opposite the gap between plates 2 and 3. In FIG. 3-b, the effective sensing area, opposite the two gaps, is doubled without doubling the total footprint of the sensor. In the event that the invention is used for a laminated window having an internal conductive (and transparent) layer, such as heater grid or coating, or a solar heat-reflecting coating, a porthole (opening) is made in the conductive layer in front of the rain sensor so that the conductive layer does not shield the sensing plates from the front surface of the window.

FIG. 4 is a partially cut-away view of a first sealed capacitive rain sensor incorporating the plates as in FIG. 3-a. Sensor housing 1 is preferably electrically conductive and grounded, thereby also serving as an electrostatic shield; it is attached to inner surface 8 of the windshield, typically by means of a Silicone sealant, providing protection for the sensing plates (only plate 3 is shown) against condensation and adsorption. In order to minimize sorption as much as possible, it is advantageous to dry the space inside the enclosure prior to sealing. Printed circuit board 4 incorporates electronic circuitry which converts the sensed capacitance into an output signal. The electronic circuitry typically includes an AC source connected to one plate to provide an excitation signal, and a charge amplifier with its input connected to the second plate to sense a coupling signal. Typically the output signal of the charge amplifier is demodulated and filtered to constitute the rain sensor output. This output is then supplied to a signal processor and control unit, typically implemented by a processing system including one or more microprocessor. The functionality of the signal processor and control unit will be described further below with reference to the schematic example of FIG. 7. The electrical connection to the capacitive plates (not shown) is preferably achieved by use of silver loaded Silicone adhesive. Interconnection to the outside of the enclosure is preferably implemented by use of a connector 6 having pins which are embedded in, and electrically insulated from, housing 1.

FIG. 5 illustrates a capacitive rain sensor in accordance with a second embodiment of the invention. The construction is similar to that in FIG. 4 except that electrical connector 5 is absent and the printed circuit board is coupled to the outside of housing 1 by means of conductors 6 printed on the glass surface, typically using standard silver ink common in the windshield industry. Pads 7, shown schematically, carry studs (not shown) soldered onto them, to which a cable can be attached. To prevent the housing from shorting the printed conductors, a clearance is provided in its respective wall (—not shown), which is filled with insulating sealant, e.g., silicone. The advantage of this interconnection method is that the housing can be injection molded from a conductive polymer, avoiding the need for insulation between the housing and the connector pins as required in the implementation of FIG. 4.

It was found that even hermetically sealed rain sensors occasionally generate false wipes in response to sudden changes in the solar radiation, e.g., when entering or exiting tunnels. The reason was found to be local glass temperature transients, due to absorbed radiation, which affect the glass dielectric constant and consequently the sensed capacitance. This effect is rapid since heat is developed directly on the plates (being opaque and therefore heat absorbent) without being delayed by thermal diffusion in the glass. Although the high-pass filter described above is effective to reject false signals due to thermal diffusion from the surrounding air through the glass, sudden direct thermal heating of the electrodes and adjacent glass generates corresponding parasitic signals that are too fast to be attenuated by the high pass filter as described.

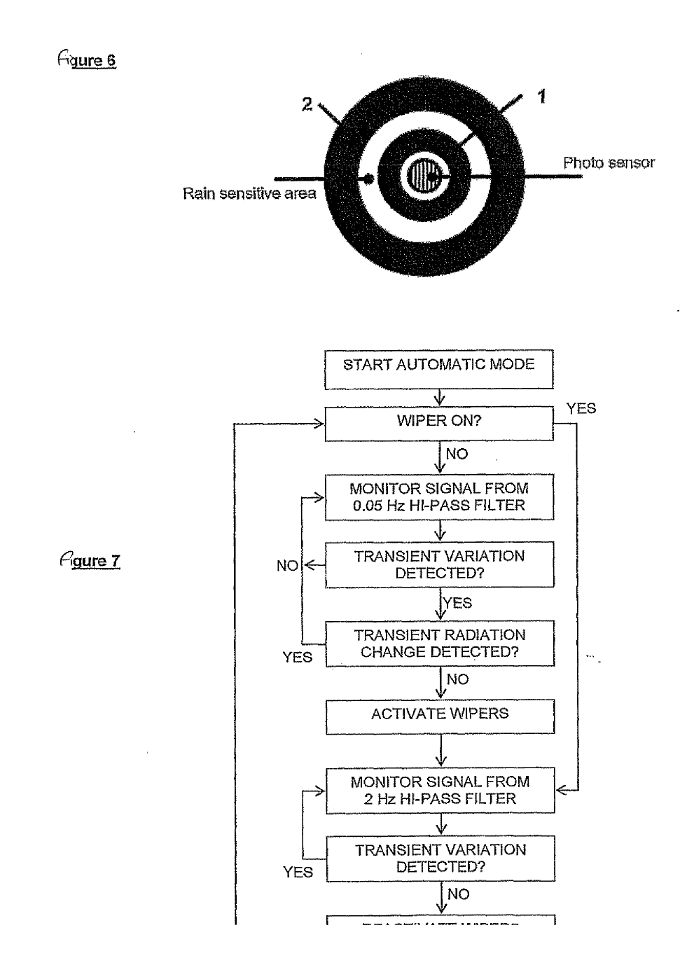

To address this problem, certain particularly preferred implementations of the present invention employ a radiation sensor for sensing solar radiation and rejecting any transient signal occurring within a short time window after an abrupt change in radiation intensity. By way of one non-limiting preferred example, FIG. 6 illustrates circular rain sensor geometry according to another excitation plate, and plate 3 is the sensing plate. An opening in plate 3 allows ambient light to illuminate a photosensitive device, such as a Silicon photodiode, preferably mounted on a printed circuit board. When a radiation change exceeds a preset threshold (typically defined in terms of magnitude and gradient), a wipe inhibit commands is issued—as shown schematically in FIG. 7. Typically, the wipe-inhibit command is only issued when the system is in the standby mode; it is not generated if the wiper is already wiping due to sensed rain. The radiation sensor can also be used for other functions, such as turning the headlamps on and off in response to ambient light conditions.

FIG. 7 illustrates the flow diagram of the wiper command generator, in accordance with a preferred embodiment of the invention. The rain sensor signal—which is proportional to the measured capacitance—is applied to two high-pass filters, as described above, with cut-on frequencies of 2 Hz and 0.05 Hz, respectively, The wiper command generator then activates or deactivates the wipers according to the output signals, together with the radiation sensor signal, preferably according to the logic flow as illustrated. It will be noted that the flow diagram is merely exemplary, and that equivalent or similar functionality may be achieved using a different logical structure. By way of one non-limiting example, the radiation sensor may operate in parallel to the main sensing logic, generating a wipe inhibiting signal for a given time period after an abrupt increase in radiation, and conditional on a current status of the wipers being “off”.

Turning now to a further particularly preferred feature of certain implementations of the present invention, the capacitive plates are in this case printed on a thin non-conductive substrate, preferably as a self-adhesive sticker, which is then attached to the inner surface of the window. For the purpose of the description and claims, the electrodes of such implementations are also described as “disposed on the surface of the window”, albeit indirectly. This embodiment has
1. It is applicable to any window regardless of its manufacturing process.
2. It is cheaper, since it does not require any printing directly on to the windshield.
3. it provides more flexibility, allowing the system to be added selectively, or retrofit to existing windows.
4. It can be applied at different locations on the window.
5. The capacitive plates can be made out of a transparent conductive material, such as Indium Tin Oxide (ITO), commonly used in touch panel displays.

The use of transparent capacitive plates is advantageous in it's own right, even for direct application on to the window, providing another significant advantage: it greatly reduces the amount of solar radiation absorbed by the electrodes compared to an opaque coating such as Silver ink. As a result, the use of transparent capacitive plates reduces local heating of the glass, as a result no false wipes Will result in response to abrupt changes in solar radiation. It should be noted that, while direct application of transparent electrodes on to the surface of the window falls within the broad scope of the present invention, direct application of ITO to the window by existing manufacturing techniques would involve an expensive vacuum process which is not economically viable for mass production. There is therefore a particular synergy to the combination of the use of ITO with a self-adhesive sticker as described above.

Unrelated to sensitivity to the presence of the wiper on the front side, as described previously, another problem was encountered with prior art capacitive rain sensors due to their parasitic sensitivity to nearby conductive objects that are interacting with far electrostatic field generated by the plates. This sensitivity may result in false wipes due to proximity of a human hand as far as 10 cm from the sensor on either side of the window. This phenomenon is especially or another part of the body close to the inner side of the window. Although the sensor housing is preferably conductive, and shields much of the far field on the inside of the window, some field still folds back from the outside and leaks through the glass, potentially interacting with nearby conductive objects, or occupants, and resulting in false wipes.

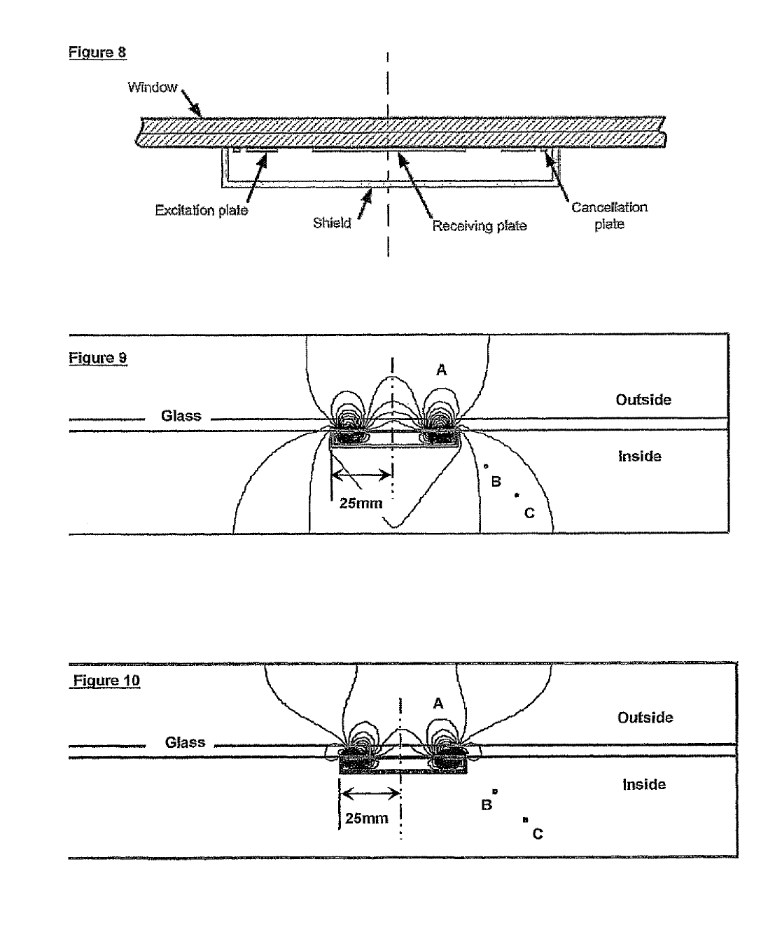

In the present invention this problem is solved using an auxiliary plate that generates an opposing far field, without substantially affecting the near field between the sensing plates on which moisture sensing is based. This approach is believed to be most effective where the excitation electrode is deployed so as to substantially surround the sensing electrode, and the compensation electrode is deployed so as to substantially surround the excitation electrode. In a particularly preferred case of a circular sensor, this layout can be implemented as a set of concentric circular electrodes. FIG. 8 illustrates a cross section of a circular rain sensor of this type, i.e., that includes an additional, peripheral, far-field cancellation plate. FIG. 9 shows a field simulation without compensation (the voltage on the cancellation plate is Vc=0). In FIG. 10 a voltage Vc=−7V peak-to-peak is applied to the field cancellation plate. This voltage is in anti phase to that of the excitation plate and thus generates an opposing field, which selectively cancels the original far electrostatic field. The table below presents the potentials at points A, B, and C, where A is in the near field region—which is sensitive to rain drops on the window outside surface, while B and C are in the compensated region on the inside of the window where the canceling field is optimized. It is evident that the field cancellation plate nearly nulls the potential at A and B—to which the parasitic sensitivity is proportional, but only slightly affects the potential at A—to which the rain sensitivity is proportional.

TABLE

| | Vc = 0 V | Vc = −7 V |
|---|---|---|
| A | 1.75 V | 1.50 V |
| B | 0.30 V | −0.005 V |
| C | 0.25 V | 0.005 V |

It will be appreciated that the above descriptions are intended only to serve as examples, and that many other embodiments are possible within the scope of the present invention as defined in the appended claims.

What is claimed is:

1. A vehicular capacitive rain sensor deployed on an internal surface of a window, the sensor having a sensing region for detecting moisture on the external surface of the window for generating wipe commands applied to a wiper deployed for wiping the external surface, the sensor comprising:
(a) at least two electrodes disposed on said internal surface and constituting a capacitance, said at least two electrodes defining a sensing region on the external surface of the window within which the presence of water detectably affects said capacitance;
(b) a housing arrangement cooperating with the internal surface of the window to enclose said electrodes, at least part of said housing arrangement being implemented as an electrostatic shield for shielding said electrodes; and
(c) electrical interconnections passing into said housing arrangement;
wherein said housing arrangement is configured to hermetically seal said electrodes so as to make said capacitance substantially insensitive to moisture adsorption.

2. A capacitive rain sensor as in claim 1, further comprising electronic circuitry associated with said electrodes and configured to generate an output signal indicative of said capacitance.

3. A capacitive rain sensor as in claim 2, further comprising a processing system for generating wipe commands derived from said output signal;

4. A capacitive rain sensor as in claim 3, wherein said processing system is configured to provide a filter with a dynamic behavior that varies depending on said output signal.

5. A capacitive rain sensor as in claim 3, wherein said processing system is
(a) when the Wiper is not activated, said processing system filters said output signal to discard variation with a frequency of less than a first cut-on frequency; and
(b) when the wiper is activated, said processing system filters said output signal to discard variation with a frequency of less than a second cut-on frequency, said second cut-on frequency being higher than said first cut-on frequency.

6. The sensor as in claim 1, wherein said electrical interconnections are implemented as printed conductors on said internal surface.

7. The sensor as in claim 1, wherein said housing arrangement is implemented primarily from conductive material so as to provide said electrostatic shield.

8. The capacitive rain sensor as in claim 3, further comprising a detector for detecting solar radiation, said processing system being responsive to an output from said detector when the wiper is not activated to prevent generation of a wipe command within a given time period after an abrupt increase in solar radiation.

9. The capacitive rain sensor as in claim 1, wherein said at least two electrodes are deposited on a surface of a flexible non-conductive layer configured for attachment to the internal surface of the window.

10. The capacitive rain sensor as in claim 9, wherein said at least two electrodes and said flexible non-conductive layer are substantially transparent.

11. The capacitive rain sensor as in claim 9, wherein said flexible non-conductive layer is coated with an adhesive for attachment to the internal surface of the window.

12. The capacitive rain sensor as in claim 1, wherein said at least two electrodes are substantially transparent.

13. The cap active rain sensor as in claim 1, wherein a first of said at least two electrodes is driven with a signal so as to generate a near electrostatic field at least in the sensing region and a far electrostatic field, the capacitive rain sensor further comprising a third electrode which is driven with an opposite signal and configured so as to generate a second far electrostatic field which opposes at least pad of said far electrostatic field of said first electrode.

14. A vehicular capacitive rain sensor deployed on an internal surface of a window, the sensor having a sensing region for detecting moisture on the external surface of the window for generating wipe commands applied to a wiper deployed for wiping the external surface, the sensor comprising:
(a) at least two electrodes disposed on said internal surface and constituting a capacitance, said at least two electrodes defining a sensing region on the external surface of the window within which the presence of water detectably affects said capacitance;
(b) a housing arrangement cooperating with the internal surface of the window to enclose said electrodes, at least part of said housing arrangement being implemented as an electrostatic shield for shielding said electrodes;
(c) electronic circuitry associated with said electrodes and configured to generate an output signal indicative of said capacitance; and
(d) a processing system for generating wipe commands derived from said output signal, wherein said processing system being configured such that:
(i) when the wiper is not activated, said processing system filters said output signal to discard variation with a frequency of less than a
(ii) when the wiper is activated, said processing system filters said output signal to discard variation with a frequency of less than a second cut-on frequency, said second cut-on frequency being higher than said first cut-on frequency.

15. A vehicular capacitive rain sensor deployed on an internal surface of a window, the sensor having a sensing region for detecting moisture on the external surface of the window for generating wipe commands applied to a wiper deployed for wiping the external surface, the sensor comprising:
(a) at least two electrodes disposed on said internal surface and constituting a capacitance, said at least two electrodes defining a sensing region on the external surface of the window within which the presence of water detectably affects said capacitance;
(b) a housing arrangement cooperating with the internal surface of the window to enclose said electrodes, at least part of said housing arrangement being implemented as an electrostatic shield for shielding said electrodes; and
(c) electronic circuitry associated with said electrodes and configured to generate an output signal indicative of said capacitance;
(d) a processing system for generating wipe commands derived from said output signal; and
(e) a detector for detecting solar radiation, said processing system being responsive to an output from said detector when the wiper is not activated to prevent generation of a wipe command within a given time period after an abrupt increase in solar radiation.

16. A vehicular capacitive rain sensor deployed on an internal surface of a window, the sensor having a sensing region for detecting moisture on the external surface of the Window for generating wipe commands applied to a wiper deployed for wiping the external surface, the sensor comprising:
(a) at least two electrodes disposed on said internal surface and constituting a capacitance, said at least two electrodes defining a sensing region on the external surface of the window within which the presence of water detectably affects said capacitance;
(b) a housing arrangement cooperating with the internal surface of the window to enclose said electrodes, at least part of said housing arrangement being implemented as an electrostatic shield for shielding said electrodes; and
wherein said at least two electrodes are deposited on a surface of a flexible non-conductive layer configured for attachment to the internal surface of the window.

17. The capacitive rain sensor as in claim 16, wherein said at least two electrodes and said flexible non-conductive layer are substantially transparent.

18. The capacitive rain sensor as in claim 16, wherein said flexible non-conductive layer is coated with an adhesive for attachment to the internal surface of the window.

19. A vehicular capacitive rain sensor deployed on an internal surface of a window, the sensor having a sensing region for detecting moisture on the external surface of the window for generating wipe commands applied to a wiper deployed for wiping the external surface, the sensor comprising:
(a) at least two electrodes disposed on said internal surface and constituting a capacitance, said at least two electrodes defining a sensing region on the external surface of the window within which the presence of water detectably affects said capacitance;
(b) a housing arrangement cooperating with the internal surface of the window to enclose said electrodes, at least part of said housing arrangement being implemented as an electrostatic shield for shielding said electrodes; and
wherein said at least two electrodes are substantially transparent.

20. A vehicular capacitive rain sensor deployed on an internal surface of a window, the sensor having a sensing region for detecting moisture on the external surface of the window for generating wipe commands applied to a wiper deployed for wiping the external surface, the sensor comprising:
(a) at least two electrodes disposed on said internal surface and constituting a sensing capacitance, said at least two electrodes defining a near electrostatic field sensing region on the external surface of the window within which the presence of water detectably affects said capacitance, said electrodes further forming a far electrostatic field;
(b) at least one compensation electrode configured for forming a compensatory far electrostatic field for selectively opposing at least part of said far electrosatic field of said sensing capacitance;
(c) a housing arrangement cooperating with the internal surface of the window to enclose said electrodes, at least part of said housing arrangement being implemented as an electrostatic shield for shielding said electrodes; and
(d) electronic circuitry associated with said electrodes and configured to generate an output signal indicative of said sensing capacitance; and
(e) a processing system for generating wipe commands derived from said output signal,
wherein said electronic circuitry drives a first of said at least two electrodes with a sensing signal and said compensation electrode with an opposite signal such that at least part of the far electrostatic field of said first electrode is reduced.
